(19) United States
(12) Patent Application Publication
(10) Pub. No.: US 2026/0247572 A1
(43) Pub. Date: Aug. 20, 2026

(54) HOUSING FOR AN ELECTRONIC COMPONENT, ASSEMBLY HAVING A HOUSING, AND METHOD FOR PRODUCING A HOUSING

(71) Applicant: Lisa Draexlmaier GmbH, Vilsbiburg (DE)

(72) Inventor: Michael WORTBERG, Dorfen (DE)

(73) Assignee: Lisa Draexlmaier GmbH, Vilsbiburg (DE)

(21) Appl. No.: 19/644,230

(22) Filed: Apr. 10, 2026

Related U.S. Application Data
(63) Continuation of application No. PCT/EP2024/075391, filed on Sep. 11, 2024.

(30) Foreign Application Priority Data
Oct. 10, 2023 (DE) 10 2023 127 630.1

(51) Int. Cl. H05K 7/20

(52) U.S. Cl. CPC H05K 7/20327; H05K 7/2039

(57) ABSTRACT

A housing for accommodating an electronic component having a housing wall and a cooling element is provided. The cooling element is an integral part with the housing wall, and the cooling element and the housing wall may be obtained by a multicomponent injection molding process. The cooling element is arranged in such a way that heat created in the electronic component may be transported by the cooling element to the housing wall, and the cooling element is arranged in such a way that the electronic component may be in surface-to-surface contact with the cooling element.

### CROSS-REFERENCE TO RELATED APPLICATIONS

This application is a continuation of International Application No. PCT/EP2024/075391, filed on September 11, 2024, which claims priority to and the benefit of DE 10 2023 127 630.1 filed on October 10, 2023. The disclosures of the above applications are incorporated herein by reference.

### FIELD

The present disclosure relates to a housing for accommodating an electronic component as well as a corresponding assembly which features the housing. The present disclosure additionally relates to a method for producing the housing.

### BACKGROUND

The statements in this section merely provide background information related to the present disclosure and may not constitute prior art.

Electronic components such as, for example, circuit boards with MOSFETs or other semiconductors mounted on them, may generate a lot of heat during operation, which heat is transported away from the electronic component and discharged to the environment. A housing that protects the electronic component from external influences may impede the discharge of heat from the circuit boards to the environment. A series of measures for providing heat transport from the electronic component via the housing to the environment are known from the prior art. Cooling ribs, for example, are frequently provided on the housing to enlarge the housing surface and thus provide heat transfer from the housing to the environment. It is also known to utilize a thermal compound, which is arranged between the electronic component and the housing, and is supposed to make possible a heat transfer from the electronic component to the housing.

The application of a thermal compound on the housing in which an electronic component is to be installed provides an additional installation step during the installation of the electronic component in the housing. Air bubbles, which further reduce heat conduction from the electronic component to the housing, form frequently during application of the thermal compound.

### SUMMARY

This section provides a general summary of the disclosure and is not a comprehensive disclosure of its full scope or all of its features.

The present disclosure provides a housing for accommodating an electronic component, a corresponding assembly, and also a method for producing the housing utilizing the simplest possible structural means, which makes possible a particularly efficient cooling of the component and, at the same time, a particularly low cycle time for production of the housing and installation of the electronic component in the housing.

According to an aspect of the present disclosure, a housing for accommodating an electronic component having a housing wall and a cooling element is provided, wherein the cooling element is configured as an integral part of the housing wall, the cooling element and the housing wall may be obtained by means of a multicomponent injection molding process, especially by means of a two-component injection molding process, the cooling element is arranged in such a way that the heat produced in the electronic component is transported away to the housing wall by means of the cooling element, and the cooling element is configured and arranged in such a way that the electronic component may be in surface-to-surface contact with the cooling element.

In other words, the cooling element is configured as an integral part of the housing wall. This means that the cooling element and the housing wall are integrally bonded to each other.

In the sense of the present disclosure, an integral configuration of two components with each other means that these components are positively bonded to each other. According to the present disclosure, this positive bond is achieved by producing both components in a multicomponent injection molding process.

A multicomponent injection molding process in the sense of the present disclosure may comprise, for example, a so-called overmolding process. That is, the multicomponent injection molding process may comprise the following process: producing the housing wall as an injection molded part from a first component and subsequently overmolding the housing wall or a part of the housing wall with a second component, which in the end forms the cooling element.

A multicomponent injection molding process in the sense of the present disclosure may also comprise, for example, the simultaneous or successive injection of a first and a second component in a tool cavity, wherein the first component ultimately forms in the end the housing wall and the second component ultimately forms the cooling element.

The cooling element and the housing wall may be made from different materials.

The housing may be obtained by means of a multicomponent injection molding process, especially a two-component injection molding process.

The housing according to the present disclosure allows an improved transfer of the heat that develops in the electronic component from the housing to the environment utilizing the simplest possible structural means. In particular, the integral configuration of the cooling element with the housing wall inhibits air inclusions in the form of air gaps or air bubbles, which impede the heat transfer, from forming between the housing wall and the cooling element. Stagnant air, in particular, has thus a low heat transfer coefficient and has, as a consequence, heat insulating properties. A direct and especially a surface-to-surface contact between the cooling element and the electronic component reduces or even inhibits air inclusions between the housing wall and the cooling element. The cycle time may additionally be especially reduced during the production of the housing and the installation of the electronic component in the housing by producing the cooling element and the housing wall by means of a multicomponent injection molding process.

According to an example, the housing wall may form a receiving area for accommodating the electronic component, wherein the cooling element may be arranged in the receiving area.

The receiving area may be a receiving space.

By forming a specific receiving area for the electronic component, it is made possible an especially accurate positioning of the electronic component in the housing, so that the heat transfer from the electronic component into the housing is improved. The installation is also simplified so that the cycle time for installation of the electronic component in the housing is reduced.

According to an example, the cooling element is arranged on the side of the housing wall that faces toward the receiving area. The cooling element is arranged in the receiving area.

The heat transfer between the electronic component and the housing wall by means of the cooling element is especially improved through such an assembly of the cooling element. The heat transfer is particularly efficient here and improved.

According to one form, the cooling element can feature an elastomer. The cooling element is made from the elastomer.

The elastomer may be a silicone-based elastomer, such as, for example, silicone rubber. As an alternative or in addition, the elastomer may be a thermoplastic elastomer, such as, for example, Styrene-Butadiene-Styrene (SBS), Styrene-Ethylene-Butylene-Styrene (SEBS) and/or Styrone-Ethylene-Butylene-Styrene-Copolymer. As an alternative or in addition, the elastomer may be a polyester-based elastomer.

Elastomers offer, on the one hand, a high thermal stability and, on the other hand, a high heat transfer coefficient, so that elastomers are particularly suitable for use as cooling element in the sense of the present disclosure. For the most part, elastic elastomers additionally make possible a particular surface-to-surface contact of the cooling element with the electronic component, so that air inclusions are particularly effectively inhibited.

The cooling element may be configured to have tolerance-compensating properties. The cooling element may have a contact surface for contacting the electronic components, wherein the contact surface may be configured in such a way that the contact surface may be adapted to the surface of the electronic component. The contact surface may be configured in such a way that the contact surface has a negative shape of the electronic component. The contact surface may be configured in such a way that the contact surface nestles against the surface of the electronic component. The contact surface may have a 3D contour.

As an alternative or in addition, the cooling element may comprise a thermoplastic and/or a duroplastic material.

The housing wall comprises a thermoplastic, especially polypropylene or polyamide. As an alternative or in addition, the housing wall may comprise an elastomer. As an alternative or in addition, the housing wall may have a fiber-reinforced plastic, such as, for example, a glass-fiber reinforced plastic having a thermoplastic or duroplastic material matrix, especially with polypropylene or polyamide as plastic matrix. In addition or as an alternative, the housing wall may comprise a metal which may be obtained, for example, by means of a metal powder injection molding process.

According to an example, the cooling element may be electrically isolating. For this purpose, the cooling element may be manufactured from electrically isolating material. As an alternative or in addition, the cooling element may have an isolation element such as, for example, an isolating film. For this purpose, the isolating film may, for example, be embedded and/or arranged on a contact surface for contacting the electronic component by means of the cooling element.

Isolating in the sense of the present disclosure may mean that the cooling element has a high specific electric resistance, in particular a specific electric resistance, which is greater than 10¹⁰ Ω·cm.

An electrically isolating property of the cooling element makes possible an electric isolation of the electronic component from the housing wall by using the simplest possible structural means. Other isolating elements may be fully omitted, so that the cycle time for production of the housing and installation of the electronic component in the housing may be further reduced.

According to an example, the cooling element may feature a phase change material element.

A phase change material element in the sense of the present disclosure comprises a phase change material. A phase change material may absorb and emit heat within the scope of phase transitions. A phase change material may thus absorb heat within a specific temperature range, wherein the thermal energy is used in part to produce a phase change of the material.

An especially effective heat transition and heat management may be achieved in the cooling element by using a phase change material element. This has a consequence that the electronic component may be especially effectively cooled.

According to another aspect of the present disclosure, an assembly featuring a housing according to the present disclosure is provided and an electronic component, wherein the electronic component is installed in a housing.

The electronic component may be a circuit board. The circuit board may feature one or several semiconductors, such as, for example, one or several MOSFET and/or other transistors.

The assembly according to the present disclosure makes possible an improved transfer of the heat created in the electronic component from the housing to the environment. In addition, the cycle time for producing the housing and the installation assembly may be reduced in particular by producing the cooling element and the housing wall by means of a multicomponent injection molding process.

According to an example, the electronic component may feature at least one heat sink which is in contact with the cooling element.

The direct contacting of the heat sink or sinks of the electronic component by the cooling element makes possible a particularly efficient cooling of the electronic component since the heat may be discharged to the environment in a particularly effective manner by means of the cooling element.

The electronic component, especially the circuit board, may feature a component side on which at least one electronic component, such as, for example, a semiconductor, in particular a MOSFET, and/or an electric resistant is installed. The cooling element may be in surface-to-surface contact with the component side of the electronic component, especially the circuit board.

According to another aspect of the present disclosure, a method for producing a housing according to the present disclosure and for installing an electronic component in the housing is provided featuring the following: making available a first material for producing the housing wall, making available a second material for producing the cooling element, and producing a housing wall and the cooling element that is integrally bonded to the housing wall by means of a multicomponent injection molding process, in particular by means of a two-component injection molding process.

The method according to the present disclosure allows a particularly short cycle time for producing the housing and installing the electronic component in the housing, which may be reduced by producing the cooling element and the housing wall by means of a multicomponent injection molding process.

The method may additionally include the following: installing an electronic component in the housing.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a plan view of a housing of the present disclosure according to a first example; and

FIG. 2 is a cross-sectional view of the housing of the present disclosure according to the first example along the intersecting axis A-A depicted in FIG. 1.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

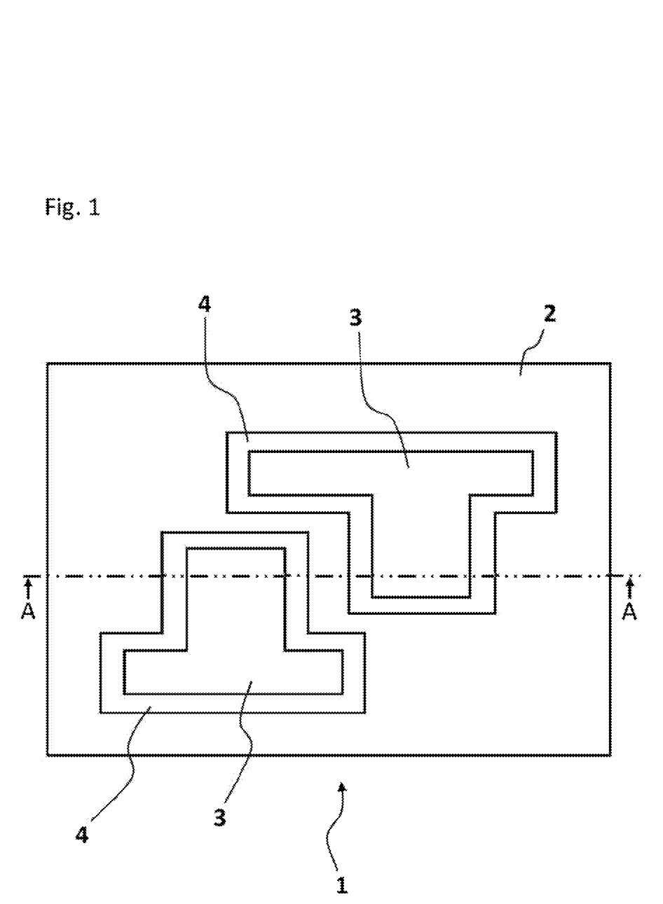

FIG. 1 shows a housing 1 according to a first example. The housing 1 according to the first example is, as depicted, a housing plate. It means that the housing 1 has a substantially planar extension according to the first example. An additional housing cover, which is depicted in the drawings, could have a configuration corresponding to the housing plate and could serve to encase the electronic component which is arranged on the housing plate and is likewise not depicted.

According to the first example, the housing 1 has two cooling elements 3 and one housing wall 2, which are integrally bonded to each other. It can be seen especially in FIG. 1 that said cooling elements 3 can have different shapes. The shape of the respective cooling element 3 may be adapted to the shape of the electronic component or also to the shape of the electronic components. The electronic component shaped like a circuit board, which is not depicted, may have two regions in which respectively several semiconductors, such as, for example, MOSFETs, are arranged. The MOSFETs generate a lot of heat, which is to be discharged from the housing 1 to the environment in order to provide a sufficient cooling of the electronic component, which is not depicted. The surface configuration of the cooling elements 3 may accordingly be adapted to the assembly of the MOSFETs in order to provide an improved discharge of the heat. For this purpose, the electronic component, which is not depicted, is received in the housing 1.

The cooling elements 3 and the housing wall 2 are configured as mutually integral parts and may be obtained by means of a multicomponent injection molding process. It is also conceivable that the cooling elements 3, the housing 2, and the housing cover, which is not depicted, may be obtained by means of a multicomponent injection molding process.

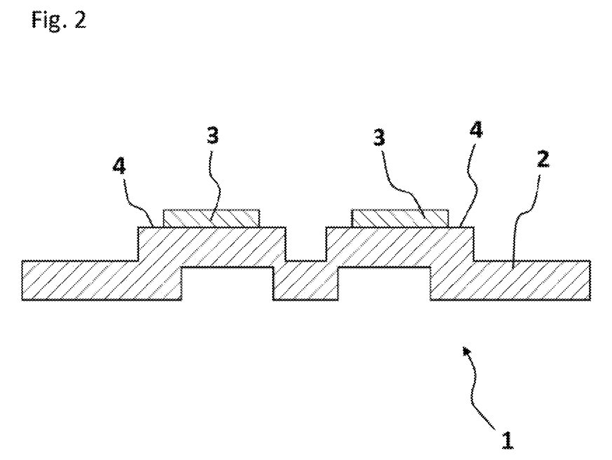

According to the first example, as can be seen especially in FIG. 2, the housing wall 2 forms two receiving areas 4. In each receiving area 4 is respectively arranged one of the cooling elements 3. According to the first example, the electronic component, which is not depicted, is arranged on said cooling elements 3. Heat is generated in the electronic component, which is not depicted, which heat is then conducted into the cooling elements 3, which are in surface-to-surface contact with the electronic component, and ultimately into the housing wall 2, which is integrally bonded to the cooling element. It is also conceivable to arrange several cooling elements 3 in a receiving area 4.

In order to improve the surface-to-surface contact of the cooling elements 3 with the electronic component, which is not depicted, the contact surface of the cooling elements 3 may be elastic and may have a flat configuration, as can be seen especially in FIG. 2. The contact surface between the respective cooling element 3 and the electronic component may be enlarged as a result of the elasticity of the cooling elements 3 since the surface of the electronic component is replicated by the contact surface of the respective cooling element 3. As an alternative or in addition, an adaptation of the contact surface of the cooling elements 3 to the electronic component may take place during the production of the housing 1. This could be achieved, for example, by means of a correspondingly configured injection mold.

As can be seen in particular in FIG. 2, the receiving areas 4 represent protrusions of the housing wall 2. As a consequence, the housing wall 2 has a substantially constant thickness. The selection of the thickness of the housing wall 2 represents a compromise between a highest possible heat conduction and a needed protective effect by the housing 1 of the electronic component, which is not depicted. It is also conceivable to provide a housing wall 2 with a different thickness. In this case, contrary to the first example, the protrusions that form the receiving area 4 cannot be compensated by the corresponding recesses that are arranged on the side opposite to the protrusions.

It can additionally be seen in FIG. 2 that the depicted housing 1 features merely the housing 2 and the two cooling elements 3; no further components are provided. The cooling elements 3 are accordingly configured as isolating according to the first example, so that the outer surface of the housing 1 is potential-free, even though the electronic component is in direct surface-to-surface contact with the housing 1 especially with the cooling elements 3. The housing 1 may, accordingly, be safely touched.

Unless otherwise expressly indicated herein, all numerical values indicating mechanical/thermal properties, compositional percentages, dimensions and/or tolerances, or other characteristics are to be understood as modified by the word “about” or "approximately" in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A housing for accommodating an electronic component, comprising:
a housing wall; and
a cooling element that is an integral part with the housing wall, the cooling element and the housing wall formed by a multicomponent injection molding process, and the cooling element is configured so that heat created in the electronic component is transported by the cooling element to the housing wall, and the electronic component is in surface-to-surface contact with the cooling element.

2. The housing according to claim 1, wherein the housing wall forms a receiving area for accommodating the electronic component, and the cooling element is arranged in the receiving area.

3. The housing according to claim 2, wherein the cooling element is arranged on a side of the housing wall that faces toward the receiving area.

4. The housing according to claim 1, wherein the cooling element has a contact surface to contact the electronic component, and the contact surface is configured to correspond with a surface of the electronic component.

5. The housing according to claim 4, wherein the contact surface is configured to have a negative shape of the electronic component.

6. The housing according to claim 4, wherein the contact surface is configured to nestle against the surface of the electronic component.

7. The housing according to claim 4, wherein the contact surface has a three-dimensional contour.

8. The housing according to claim 1, wherein the cooling element includes an elastomer.

9. The housing according to claim 1, wherein the cooling element is electrically isolating.

10. The housing according to claim 1, wherein the cooling element includes a phase change material element.

11. An assembly, comprising:
the housing according to claim 1; and
an electronic component,
wherein the electronic component is installed in the housing.

12. The assembly according to claim 11, wherein the electronic component has at least one heat sink which is contact with the cooling element.

13. A method for producing a housing for accommodating an electronic component, comprising:
providing a first material for producing a housing wall;
providing a second material for producing a cooling element; and
producing the housing wall with the cooling element integrally bonded to the housing wall by a multicomponent injection molding process.
